(19) United States
(12) Patent Application Publication
(10) Pub. No.: US 2006/0081833 A1
(43) Pub. Date: Apr. 20, 2006

(54) Package structure of light-emitting device

(76) Inventors: Yu-Chin Peng, Chuper City (TW); Ya-Li Chen, Chuper City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/296,452

(22) Filed: Dec. 8, 2005

(30) Foreign Application Priority Data
Feb. 14, 2004 (TW) 093220099

(51) Int. Cl. H01L 29/06

(52) U.S. Cl. 257/13

(57) ABSTRACT

A package structure of light-emitting device comprises a substrate. Two lines are formed on the substrate. An insulating layer is formed between two lines. A plurality of light-emitting sources are formed on the substrate for generating the light. Each light-emitting source has a positive electrode and a negative electrode. A plurality of leading wires are respectively connected to two lines from the positive electrode and the negative electrode of the light-emitting source to form an electrical connection.

### BACKGROUND OF THE INVENTION

1. Field of the Invention

The present invention relates to a light-emitting device and more particularly, to a package structure of light-emitting device.

2. Description of the Related Art

The light emitting diode (LED) is a semiconductor element, and has the characteristics of small size, long lifespan and low power consumption. Therefore, LED is generally utilized in indication and display devices, and the application territory thereof includes backlight source of a mobile phone, indication light of consumptive electronic products, industrial instrument, instrument panel light and brake light of an automobile, spectacular advertising display, and traffic signal light.

FIG. 1 is a schematic diagram of conventional light-emitting diode. The light-emitting diode 1 comprises a plurality of lead frames 10 and a plurality of chips 12 formed thereon. The chip 12 is connected to the lead frame 10 by the lead wire 14 to form an electrical connection. The chip 12 is covered by the transparent housing 16, thereby reflecting the light from the chip by the two sides of the light-reflecting area 18, in order to emit the light through the transparent housing 16.

However, the lead frame 10 and the light-reflecting area 18 in the above-mentioned light-emitting diode 1 occupy a lot of spaces, resulting in increasing the unit area. When arranged in the matrix arrangement, the density of the chip is not enough to achieve the light-emitting source having the small area and high performance.

In view of this, the present invention provides a package structure of light-emitting device to overcome the above-mentioned disadvantages.

### SUMMARY OF THE INVENTION

The present invention has been accomplished under the circumstances in view. It is one object of the present invention to provide a package structure of light-emitting device, which integrates the lead frame and the light-reflecting area, thereby achieving the light-emitting source having the minimum area and the maximum amount and reducing the encapsulated area.

It is another object of the present invention to provide a package structure of light-emitting, which the reflective layer is coated to substitute for the light-reflecting area, thereby reducing the thickness of the light-emitting source.

To achieve these and other objects of the present invention, the package structure of light-emitting device comprises a substrate. Two lines are formed on the substrate. An insulating layer is formed between two lines. A plurality of light-emitting sources are formed on the substrate for generating the light. Each light-emitting source has a positive electrode and a negative electrode. A plurality of leading wires are respectively connected to two lines from the positive electrode and the negative electrode of the light-emitting source to form an electrical connection.

Other advantages of the present invention will become apparent from the following description taken in conjunction with the accompanying drawings wherein are set forth, by way of illustration and example, certain embodiments of the present invention.

### BRIEF DESCRIPTION OF THE DRAWINGS

The foregoing aspects and many of the accompanying advantages of this invention will become more readily appreciated as the same becomes better understood by reference to the following detailed description, when taken in conjunction with the accompanying drawings, wherein:

FIG. 1 is a schematic diagram of conventional light-emitting diode;

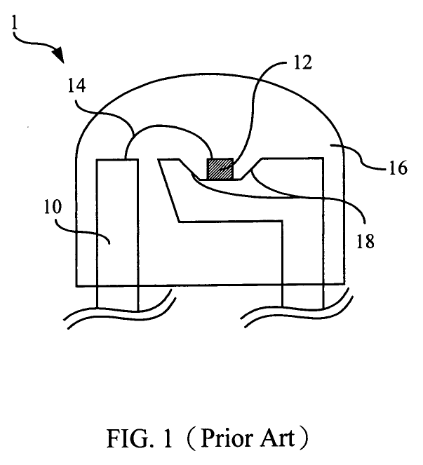

FIG. 2 is a schematic diagram of a package structure according to one embodiment of the present invention;

FIG. 3 is a top view of a package structure according to one embodiment of the present invention; and

FIG. 4 is a top view of the matrix light-emitting sources according to one embodiment of the present invention; and

FIG. 5 is a perspective view of an alternative embodiment of the present invention.

### DETAILED DESCRIPTION OF THE PREFERRED EMBODIMENT

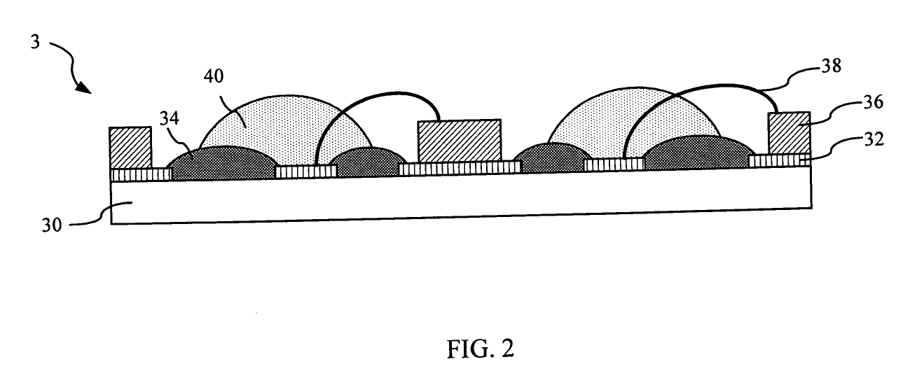

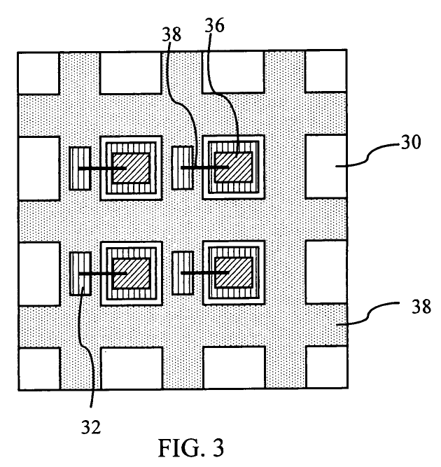

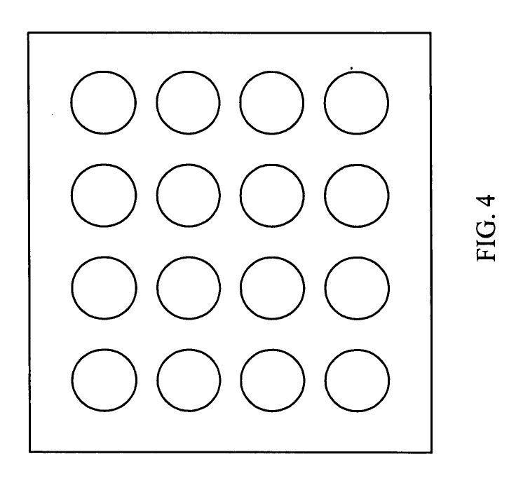

The present invention provides a package structure of light-emitting device, as shown in FIGS. 2 and 3. The light-emitting device 3 comprises a substrate 30, which is composed of a circuit board, a silicon wafer, a glass, and non-metal material. Two lines 32 are formed on the surface of the substrate 30. A plurality of light-emitting sources 36 are formed on the substrate 30, for examples, the light-emitting diodes. The arrangement of light-emitting sources 36 is represented by a matrix arrangement shown in FIG. 4, or represented by any other arrangement. For examples, three light-emitting sources are positioned into one module for generating the light, etc. Each light-emitting source 36 has two solder pads used as two electrodes, a positive electrode and a negative electrode. Two lines respectively provide for connecting the positive electrode and the negative electrode. An insulating layer 34 is formed between two lines, and a plurality of leading wires are respectively connected to two lines from the positive electrode and the negative electrode of the light-emitting source 36 to form an electrical connection. A plurality of reflective layers are formed on the substrate 30, and positioned between the light-emitting sources 36 to reflect the light from the light-emitting sources 36.

The reflective layers 40 are composed of metal and polymeric mixture or flexible material. The metal is selected from the group consisting of silver, aluminum, zinc, and chromium. The metal also can be ceramic material, or other materials which can reflect the light. The light-emitting device 3 also comprise a plurality of protection layers to cover the leading wires 38 in order to protect the leading wires 38. The reflective layers 40 are coated on the substrate 30 by a coating. The height of the reflective layer 40 is higher than the height of the light-emitting source 36.

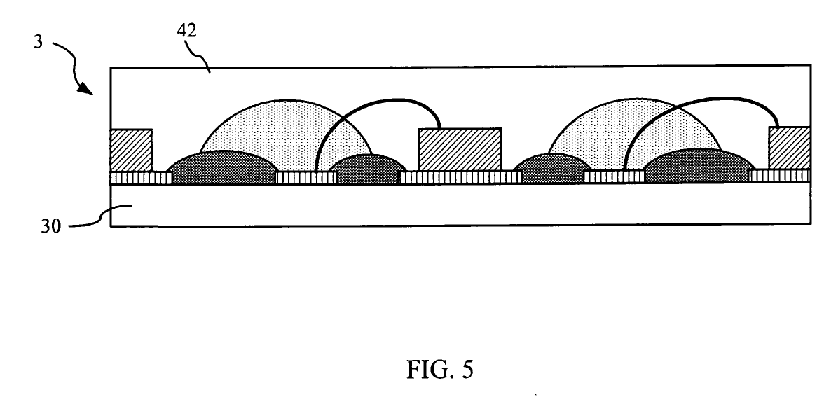

As shown in FIG. 5, after the light-emitting device 3 encapsulated, an encapsulated glue is coated on the substrate 30 to cover all devices, for examples, epoxy resin (ER).

The present invention provides a package structure of light-emitting device, which integrates the lead frame and the light-reflecting area. The reflective layers reflect the light to achieve the light-emitting source having the minimum area and the maximum amount, thereby having the high-density light-emitting source to increase the performance and reduce the thickness of the light-emitting device.

Although a particular embodiment of the invention has been described in detail for purposes of illustration, various modifications and enhancements may be made without departing from the spirit and scope of the invention.

What the invention claimed is:

1. A package structure of light-emitting device, comprising:
a substrate having two lines formed thereon, an insulating layer formed between two lines, a plurality of light-emitting sources formed on said substrate, each light-emitting source having a positive electrode and a negative electrode for generating the light;
a plurality of leading wires respectively connecting to the two lines from the positive electrode and the negative electrode of the fight-emitting source for forming an electrical connection; and
a plurality of reflective layers formed on said substrate and positioned between the light-emitting sources for reflecting the light from the light-emitting sources.

2. The package structure of light-emitting device as claimed in claim 1, wherein the material of said substrate comprises a circuit board, a silicon wafer, a glass, and non-metal material.

3. The package structure of light-emitting device as claimed in claim 1, wherein the light-emitting sources are the light emitting diodes.

4. The package structure of light-emitting device as claimed in claim 1, wherein the reflective layers are composed of metal and polymeric mixture or flexible material.

5. The package structure of light-emitting device as claimed in claim 4, wherein the metal is selected from the group consisting of silver, aluminum, zinc, and chromium.

6. The package structure of light-emitting device as claimed in claim 1, wherein the reflective layers comprise ceramic materials.

7. The package structure of light-emitting device as claimed in claim 1, further comprising a plurality of protection layers for covering the lines to protect.

8. The package structure of light-emitting device as claimed in claim 1, wherein the reflective layers are coated on the substrate.

9. The package structure of light-emitting device as claimed in claim 1, wherein the height of the reflective layers is higher than the height of the light-emitting sources.
